(19) United States
(12) Patent Application Publication
(10) Pub. No.: US 2026/0082938 A1
(43) Pub. Date: Mar. 19, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Masato YASUI, Ibo Hyogo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/063,429

(22) Filed: Feb. 26, 2025

(30) Foreign Application Priority Data
Sep. 17, 2024 (JP) 2024-159851

(51) Int. Cl. H10W 70/40; H10W 72/00; H10W 72/60; H10W 90/00

(52) U.S. Cl. CPC H10W 70/424; H10W 72/631; H10W 72/634; H10W 72/886; H10W 90/736; H10W 90/766

(57) ABSTRACT

A semiconductor device includes a semiconductor chip having a first chip surface and a second chip surface, and a connector member having a bonding portion that faces the first chip surface and a connection portion. The connection portion is connected to an end portion of the bonding portion on one side in a second direction, and located on the other side in a first direction toward one side in the second direction. The bonding portion has a first bonding surface bonded to the first chip surface. A first recessed portion that is recessed on one side in the first direction and is open to the other side in the second direction is provided in the first bonding surface. A dimension of the first recessed portion in the second direction is 40% or more and 60% or less of a dimension of the bonding portion in the second direction.

### CROSS-REFERENCE TO RELATED APPLICATION

This application is based upon and claims the benefit of priority from Japanese Patent Application No. 2024-159851, filed on Sep. 17, 2024, the entire contents of which are incorporated herein by reference.

### FIELD

Embodiments described herein relate to a semiconductor device.

### BACKGROUND

There is known a semiconductor device in which one surface of a chip is bonded to a lead frame by a bonding material such as solder, and the other surface of the chip is bonded to a connector. In such a semiconductor device, when the connector has a bent portion that bends toward the lead frame, the molten bonding material tends to flow toward the bent portion when the bonding material is reflowed in a manufacturing process of the semiconductor device. When the chip is pulled by the bonding material flowing toward the bent portion, there is a risk that the chip will be bonded to the lead frame and the connector in an inclined state.

### BRIEF DESCRIPTION OF THE DRAWINGS

FIG. 1 is a plan view showing a semiconductor device according to an embodiment.

FIG. 2 is a cross-sectional view showing the semiconductor device according to the embodiment, taken along line II-II of FIG. 1.

FIG. 3 is a cross-sectional view showing the semiconductor device according to the embodiment, taken along line III-III of FIG. 1.

FIG. 4 is a first cross-sectional view showing a manufacturing process of the semiconductor device according to the embodiment.

FIG. 5 is a first cross-sectional view showing a manufacturing process of a semiconductor device according to a comparative example.

FIG. 6 is a second cross-sectional view showing the manufacturing process of the semiconductor device according to the comparative example.

FIG. 7 is a second cross-sectional view showing the manufacturing process of the semiconductor device according to the embodiment.

FIG. 8 is a third cross-sectional view showing the manufacturing process of the semiconductor device according to the embodiment.

### DETAILED DESCRIPTION

A semiconductor device according to an embodiment includes a semiconductor chip having a first chip surface that faces one side in a first direction and a second chip surface that faces the other side in the first direction, a connector member having a bonding portion that faces the first chip surface in the first direction and a connection portion connected to the bonding portion, and a lead frame that faces the second chip surface in the first direction. The connection portion is connected to one end portion of the bonding portion in a second direction perpendicular to the first direction and is located on the other side in the first direction toward the one side in the second direction. The bonding portion has a first bonding surface bonded to the first chip surface by a first bonding material. The lead frame has a second bonding surface bonded to the second chip surface by a second bonding material. A first recessed portion that is recessed to one side in the first direction and is open to the other side in the second direction is provided in the first bonding surface. A portion of the first bonding material is accommodated inside the first recessed portion. A dimension of the first recessed portion in the second direction is 40% or more and is 60% or less of a dimension of the bonding portion in the second direction.

Hereinafter, the semiconductor device according to the embodiment will be described with reference to the drawings.

A first direction D1 shown in each of drawings is an up-down direction of the semiconductor device. The side (the +D1 side) to which an arrow in the first direction D1 points is the upper side of the semiconductor device. The side (the −D1 side) opposite to the side to which the arrow in the first direction D1 points is the lower side of the semiconductor device. In the following description, the up-down direction of the semiconductor device will be referred to as the “up-down direction” or “first direction D1,” the upper side of the semiconductor device will be referred to as the “upper side” or “one side in the first direction D1,” and the lower side of the semiconductor device will be referred to as the “lower side” or “the other side in the first direction D1.”

The second direction D2 shown in each of drawings is a direction perpendicular to the first direction D1. In the following description, the side (the +D2 side) to which an arrow in the second direction D2 points will be referred to as “one side in the second direction D2,” and the side (the −D2 side) opposite to the side to which the arrow in the second direction D2 points will be referred to as “the other side in the second direction D2.”

A third direction D3 shown in each of drawings is a direction perpendicular to both the first direction D1 and the second direction D2. In the following description, the side (the +D3 side) to which an arrow in the third direction D3 points will be referred to as “one side in the third direction D3,” and the side (the −D3 side) opposite to the side to which the arrow in the third direction D3 points will be referred to as “the other side in the third direction D3.”

In this specification, terms such as “orthogonal,” “same,” and “similar,” and values of lengths and angles which specify a shape of each of parts constituting a semiconductor device and a degree of a relative positional relationship between the parts will not be bound by their strict meanings but will be interpreted to include a range to which similar functions can be expected and a range of design tolerances. Furthermore, the drawings are schematic and conceptual, and dimensions of each of the parts constituting the semiconductor device and dimensional proportions between the parts are not necessarily the same as those in reality. Furthermore, even when the same part is shown, the dimensions and proportions may be different in each of the drawings.

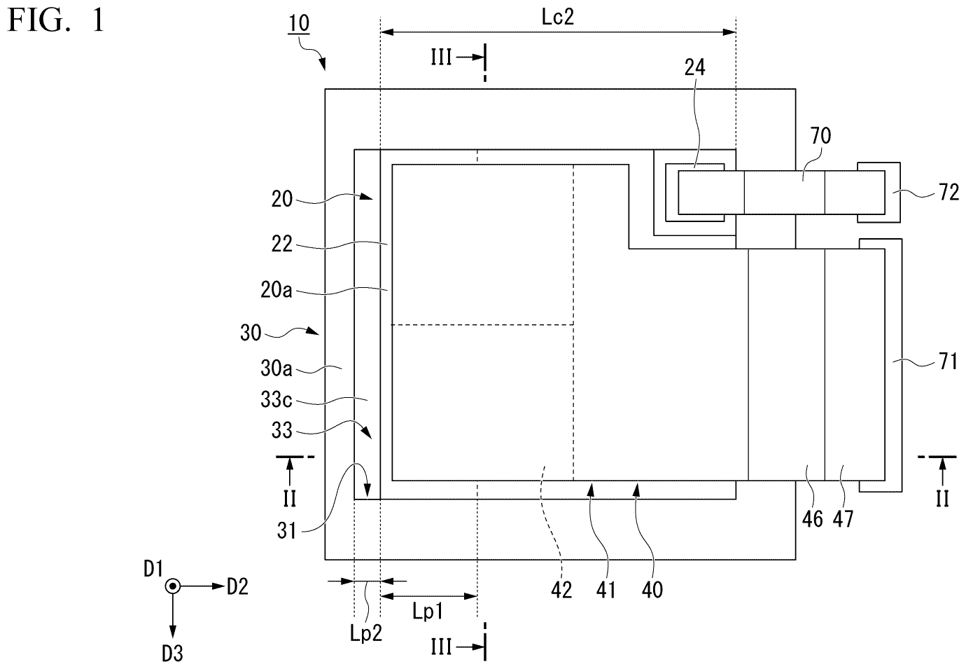

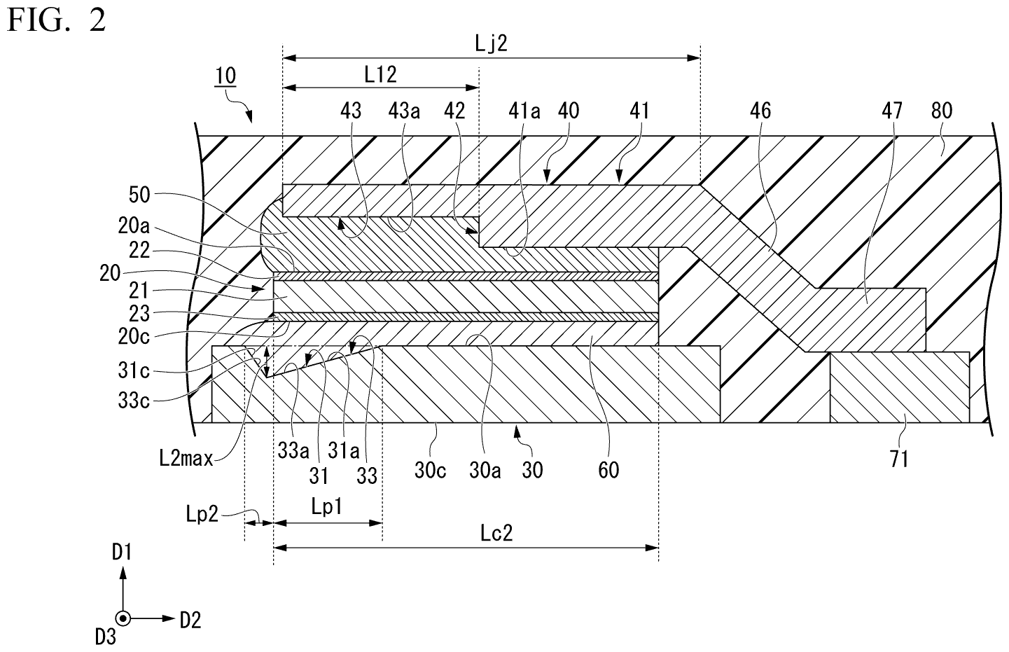

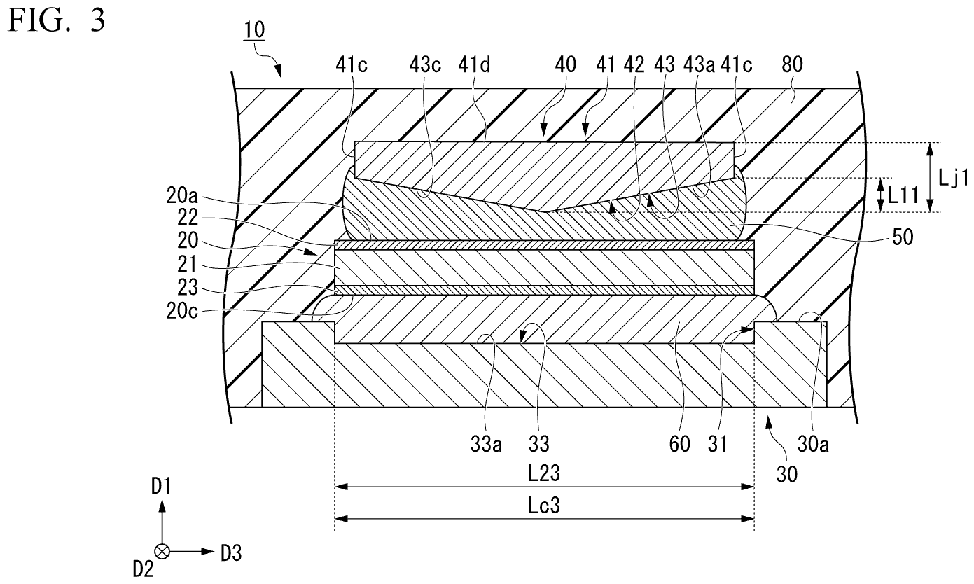

FIG. 1 is a plan view showing a semiconductor device 10 according to this embodiment. FIG. 2 is a cross-sectional view showing the semiconductor device 10 according to this embodiment, taken along line II-II of FIG. 1. FIG. 3 is a cross-sectional view showing the semiconductor device 10 of this embodiment, taken along line III-III of FIG. 1. The semiconductor device 10 of this embodiment is a semiconductor device such as a metal-oxide-semiconductor field-effect transistor (MOSFET) or an insulated gate bipolar transistor (IGBT). As shown in FIG. 1, the semiconductor device 10 includes a semiconductor chip 20, a lead frame 30, a connector member 40, a second connector member 70, and electrode terminals 71 and 72. As shown in FIG. 2, the semiconductor device 10 includes a resin part 80.

In the up-down direction, the semiconductor chip 20 is disposed between the lead frame 30 and the connector member 40. The semiconductor chip 20 has a plate shape that extends in a direction perpendicular to the up-down direction. A plate surface of the semiconductor chip 20 faces in the up-down direction. As shown in FIG. 1, when seen in the up-down direction, the semiconductor chip 20 has a generally rectangular shape with two sides extending in the second direction D2 and the other two sides extending in the third direction D3. As shown in FIG. 2, the semiconductor chip 20 includes a substrate 21, a first electrode 22, a second electrode 23, a first chip surface 20a, and a second chip surface 20c. As shown in FIG. 1, the semiconductor chip 20 includes a third electrode 24.

The substrate 21 shown in FIG. 2 is a semiconductor substrate made of a semiconductor material such as silicon, silicon carbide, gallium arsenide, or gallium nitride. Although not shown, when seen in the up-down direction, the substrate 21 has a generally rectangular shape with two sides extending in the second direction D2 and the other two sides extending in the third direction D3.

The first electrode 22 is formed on a surface of the substrate 21 that faces upward. In this embodiment, the first electrode 22 is a source electrode. The second electrode 23 is formed on a surface of the substrate 21 that faces downward. As shown in FIG. 1, the third electrode 24 is formed on the surface of the substrate that faces upward. The first electrode 22 and the third electrode 24 are disposed at an interval from each other in the second direction D2 and the third direction D3. Thus, the first electrode 22 and the third electrode 24 are insulated from each other. In this embodiment, the third electrode 24 is a gate electrode.

As shown in FIG. 2, the first chip surface 20a is a surface that faces upward among outer surfaces of the semiconductor chip 20, that is, that faces one side (the +D1 side) in the first direction D1. In this embodiment, the first chip surface 20a is constituted by upward facing surfaces of the substrate 21, the first electrode 22, and the third electrode 24. The second chip surface 20c is a surface that faces downward among the outer surfaces of the semiconductor chip 20, that is, that faces the other side (the −D1 side) in the first direction D1. In this embodiment, the second chip surface 20c is constituted by downward facing surfaces of the substrate 21 and the second electrode 23.

The lead frame 30 has a plate shape that extends in a direction perpendicular to the up-down direction. A plate surface of the lead frame 30 faces in the up-down direction. The lead frame 30 is located below the semiconductor chip 20. The lead frame 30 faces the second chip surface 20c in the up-down direction, that is, in the first direction D1. As shown in FIG. 1, when seen in the up-down direction, the lead frame 30 has a generally rectangular shape with two sides extending in the second direction D2 and the other two sides extending in the third direction D3. In this embodiment, a dimension of the lead frame 30 in the second direction D2 is larger than a dimension of the semiconductor chip 20 in the second direction D2, and a dimension of the lead frame 30 in the third direction D3 is larger than a dimension of the semiconductor chip 20 in the third direction D3. When seen in the up-down direction, an outer edge of the lead frame 30 surrounds an outer edge of the semiconductor chip 20. An end portion of the lead frame 30 on the other side (the −D2 side) in the second direction D2 is located on the other side in the second direction D2 with respect to an end portion of the semiconductor chip 20 on the other side in the second direction D2. The lead frame 30 has conductivity. In this embodiment, the lead frame 30 is made of copper. The lead frame 30 is manufactured, for example, by pressing a copper plate. The lead frame 30 may be made of other metal materials such as silver, gold, or the like. As shown in FIG. 2, the lead frame 30 has a second bonding surface 30a.

The second bonding surface 30a is a surface that faces upward among outer surfaces of the lead frame 30. The second bonding surface 30a is bonded to the second chip surface 20c by a second bonding material 60. Thus, the lead frame 30 and the semiconductor chip 20 are bonded together. In this embodiment, the second bonding material 60 is solder. The second bonding material 60 is an alloy containing metals such as tin and lead. As described below, the second bonding material 60 is formed by reflowing a paste-like second bonding material 60P and thus solidifying a melted liquid second bonding material 60L. The second bonding material 60 may be a solder containing other metallic materials such as antimony and gold. The second bonding material 60 may be a bonding material made of a resin, such as an epoxy resin or a polyimide resin, and metal particles, such as copper or silver, dispersed in the resin. The second bonding material 60 has conductivity. Therefore, the lead frame 30 and the second electrode 23 are electrically connected to each other via the second bonding material 60.

A second recessed portion 31 is provided in the second bonding surface 30a. The second recessed portion 31 is a recess recessed downward from the second bonding surface 30a, that is, toward the other side (the −D1 side) in the first direction D1. Part of the second bonding material 60 is accommodated inside the second recessed portion 31. The second recessed portion 31 is provided in a portion of the second bonding surface 30a on the other side (the −D2 side) in the second direction D2. As shown in FIGS. 1 and 2, when seen in the first direction D1, the second recessed portion 31 overlaps an edge portion of the semiconductor chip 20 on the other side in the second direction D2.

As shown in FIG. 3, the second recessed portion 31 extends in the third direction D3. In this embodiment, a dimension L23 of the second recessed portion 31 in the third direction D3 is equal to or smaller than a dimension Lc3 of the semiconductor chip 20 in the third direction D3. In this embodiment, the dimension L23 of the second recessed portion 31 in the third direction D3 is the same as the dimension Lc3 of the semiconductor chip 20 in the third direction D3. The dimension L23 of the second recessed portion 31 in the third direction D3 may be smaller than the dimension Lc3 of the semiconductor chip 20 in the third direction D3. In this embodiment, when seen in the up-down direction, an edge portion of the second recessed portion 31 on one side (the +D3 side) in the third direction D3 overlaps an edge portion of the semiconductor chip 20 on one side in the third direction D3, and when seen in the up-down direction, an edge portion of the second recessed portion 31 on the other side (the −D3 side) in the third direction D3 overlaps an edge portion of the semiconductor chip 20 on the other side in the third direction D3. When the dimension L23 of the second recessed portion 31 in the third direction D3 is smaller than the dimension Lc3 of the semiconductor chip 20 in the third direction D3, preferably, the edge portion of the second recessed portion 31 on one side in the third direction D3 is located on the other side in the third direction D3 with respect to the edge portion of the semiconductor chip 20 on one side in the third direction D3, and the edge portion of the second recessed portion 31 on the other side in the third direction D3 is located on one side in the third direction D3 with respect to the edge portion of the semiconductor chip 20 on the other side in the third direction D3. Thus, in a reflow process P02 described below, it is possible to curb the liquid second bonding material 60L leaking out from a gap between the second recessed portion 31 and the semiconductor chip 20 onto the second bonding surface 30a. Therefore, it is possible to curb an adhesive strength between the lead frame 30 and the resin part 80 decreasing.

The dimension L23 of the second recessed portion 31 in the third direction D3 may be larger than the dimension Lc3 of the semiconductor chip 20 in the third direction D3. As shown in FIG. 2, the second recessed portion 31 has a first portion 31a, a second portion 31c, and a second inner surface 33.

The first portion 31a is a portion of the second recessed portion 31 on one side (the +D2 side) in the second direction D2. More specifically, the first portion 31a is a portion of the second recessed portion 31 that overlaps the semiconductor chip 20 when seen in the up-down direction, that is, the first direction D1. In this embodiment, an end portion of the first portion 31a on one side in the second direction D2 is located on the other side (the −D2 side) in the second direction D2 with respect to both a center portion of the semiconductor chip 20 in the second direction D2 and a center portion of the lead frame 30 in the second direction D2. In this embodiment, a third ratio R3 which is a ratio of a dimension Lp1 of the first portion 31a in the second direction D2 to a dimension Lc2 of the semiconductor chip 20 in the second direction D2 is 25% or more and 33% or less. The third ratio R3 may be smaller than 25% or larger than 33%.

The second portion 31c is a portion of the second recessed portion 31 on the other side (the −D2 side) in the second direction D2. More specifically, the second portion 31c is a portion of the second recessed portion 31 that is located on the other side in the second direction D2 with respect to the semiconductor chip 20 when seen in the up-down direction, that is, the first direction D1. That is, the second portion 31c is located on the other side in the second direction D2 with respect to the semiconductor chip 20. The second portion 31c is connected to the first portion 31a in the second direction D2. In this embodiment, a dimension Lp2 of the second portion 31c in the second direction D2 is 0.05 mm or more and 0.15 mm or less. The dimension Lp2 of the second portion 31c in the second direction D2 may be smaller than 0.05 mm or larger than 0.15 mm.

The second inner surface 33 is a surface of the inner surface that faces upward, that is, faces one side (the +D1 side) in the first direction D1 among inner surfaces of the second recessed portion 31. As shown in FIG. 3, the second inner surface 33 extends in the third direction D3. As shown in FIG. 2, the second inner surface 33 has a third inner surface portion 33a and a fourth inner surface portion 33c.

The third inner surface portion 33a is a portion of the second inner surface 33 on one side (the +D2 side) in the second direction D2. The third inner surface portion 33a is an inclined surface that is located downward, that is, on the other side (the −D1 side) in the first direction D1 as it goes from an end portion of the second inner surface 33 on one side in the second direction D2 to the other side (the −D2 side) in the second direction D2. In this embodiment, the third inner surface portion 33a is a flat surface that extends linearly between the lower side and the other side in the second direction D2 when seen in the third direction D3. The third inner surface portion 33a may be a curved surface that extends in a curved shape between the lower side and the other side in the second direction D2 when seen in the third direction D3.

The fourth inner surface portion 33c is a portion of the second inner surface 33 on the other side (the −D2 side) in the second direction D2. The fourth inner surface portion 33c is an inclined surface that is located downward, that is, on the other side (the −D1 side) in the first direction D1 as it goes from the end portion of the second inner surface 33 on the other side in the second direction D2 toward one side (the +D2 side) in the second direction D2. In this embodiment, the fourth inner surface portion 33c is a flat surface that extends linearly between the lower side and one side in the second direction D2 when seen in the third direction D3. An end portion of the fourth inner surface portion 33c on one side in the second direction D2 is connected to an end portion of the third inner surface portion 33a on the other side in the second direction D2. Therefore, in this embodiment, the second inner surface 33 has a V-shape that protrudes downward when seen in the third direction D3. The fourth inner surface portion 33c may be a curved surface that extends in a curved shape between the lower side and one side in the second direction D2 when seen in the third direction D3.

In this embodiment, a maximum dimension L2max of the second recessed portion 31 in the first direction D1 is 15 μm or more. The maximum dimension L2max of the second recessed portion 31 in the first direction D1 is a maximum depth of the second recessed portion 31. In this embodiment, the maximum dimension L2max is a distance in the first direction D1 between a portion at which the third inner surface portion 33a and the fourth inner surface portion 33c are connected and the second bonding surface 30a. In this embodiment, the portion at which the third inner surface portion 33a and the fourth inner surface portion 33c are connected in the second direction D2 is located near an edge portion of each of the semiconductor chip 20 and the second electrode 23 on the other side (the −D2 side) in the second direction D2. That is, the deepest portion of the second recessed portion 31 is located near an edge portion of the second electrode 23 on the other side in the second direction D2.

The connector member 40 has a plate shape that extends in the second direction D2. The connector member 40 has conductivity. In this embodiment, the connector member 40 is made of copper. The connector member 40 is manufactured, for example, by pressing a copper plate. The connector member 40 may be made of other metallic materials such as silver, gold, or the like. The connector member 40 has a bonding portion 41, a connection portion 46, and a terminal portion 47.

The bonding portion 41 is located above the semiconductor chip 20. A plate surface of the bonding portion 41 is directed in the up-down direction. The bonding portion 41 faces the first chip surface 20a in the up-down direction, that is, in the first direction D1. As shown in FIG. 1, the bonding portion 41 extends in the second direction D2. An end portion of the bonding portion 41 on one side (the +D3 side) in the third direction D3 is located on the other side (the −D3 side) in the third direction D3 with respect to an end portion of the semiconductor chip 20 on one side in the third direction D3. An end portion of the bonding portion 41 on the other side in the third direction D3 is located on one side in the third direction D3 with respect to an end portion of the semiconductor chip 20 on the other side in the third direction D3. An end portion of the bonding portion 41 on the other side (the −D2 side) in the second direction D2 is located on one side (the +D2 side) in the second direction D2 with respect to an end portion of the semiconductor chip 20 on the other side in the second direction D2. An end portion of the bonding portion 41 on one side in the second direction D2 is located on one side in the second direction D2 with respect to an end portion of the semiconductor chip 20 on one side in the second direction D2. A notch is provided in a portion of the bonding portion 41 on one side in the second direction D2 and on the other side in the third direction D3. Thus, when seen in the up-down direction, the bonding portion 41 does not overlap the third electrode 24. As shown in FIG. 2, the bonding portion 41 has a first bonding surface 41a.

The first bonding surface 41a is a surface that faces downward among outer surfaces of the bonding portion 41. The first bonding surface 41a is bonded to the first chip surface 20a by a first bonding material 50. Thus, the connector member 40 and the semiconductor chip 20 are bonded together. In this embodiment, the first bonding material 50 is solder. The first bonding material 50 is an alloy containing metals such as tin and lead. As described below, the first bonding material 50 is formed by reflowing a paste-like first bonding material 50P and thus solidifying a melted first bonding material 50L. The first bonding material 50 has conductivity. Therefore, the connector member 40 and the first electrode 22 are electrically connected to each other via the first bonding material 50. In other words, the connector member 40 is electrically connected to the semiconductor chip 20 via the first bonding material 50.

A first recessed portion 42 is provided in the first bonding surface 41a. The first recessed portion 42 is a recess recessed upward from the first bonding surface 41a, that is, to one side (the +D1 side) in the first direction D1. The first recessed portion 42 is provided in a portion of the first bonding surface 41a on the other side (the −D2 side) in the second direction D2. The first recessed portion 42 is open to the other side in the second direction D2. As shown in FIG. 3, the first recessed portion 42 is open on both sides in the third direction D3. As shown in FIG. 2, part of the first bonding material 50 is accommodated in the first recessed portion 42. As shown in FIG. 3, a first ratio R1 which is a ratio of a dimension L11 of the first recessed portion 42 in the up-down direction to a dimension Lj1 of the bonding portion 41 in the up-down direction, that is, the first direction D1 is 40% or more and 60% or less. The first ratio R1 may be smaller than 40% or greater than 60%. As shown in FIG. 2, in this embodiment, a second ratio R2 which is a ratio of a dimension L12 of the first recessed portion 42 in the second direction D2 to a dimension Lj2 of the bonding portion 41 in the second direction D2 is 40% or more and 60% or less. The second ratio R2 may be smaller than 40% or may be greater than 60%. The first recessed portion 42 has a first inner surface 43.

The first inner surface 43 is a surface that faces downward, that is, the other side (the −D1 side) in the first direction D1, among inner surfaces of the first recessed portion 42. The first inner surface 43 extends in the second direction D2. As shown in FIG. 3, the first inner surface 43 has a first inner surface portion 43a and a second inner surface portion 43c.

The first inner surface portion 43a is a portion of the first inner surface 43 on one side (the +D3 side) in the third direction D3. The first inner surface portion 43a is an inclined surface that is located downward, that is, on the other side (the −D1 side) in the first direction D1, as it goes from an end portion of the first inner surface 43 on one side in the third direction D3 to the other side (the −D3 side) in the third direction D3. In this embodiment, the first inner surface portion 43a is a flat surface that extends linearly between the lower side and the other side in the third direction D3 when seen in the second direction D2. The first inner surface portion 43a may be a curved surface that extends in a curved shape between the lower side and the other side in the third direction D3 when seen in the second direction D2.

The second inner surface portion 43c is a portion of the first inner surface 43 on the other side (the −D3 side) in the third direction D3. The second inner surface portion 43c is an inclined surface that is located downward, that is, on the other side (the −D1 side) in the first direction D1, as it goes from an end portion of the first inner surface 43 on the other side in the third direction D3 to one side (the +D3 side) in the third direction D3. In this embodiment, the second inner surface portion 43c is a flat surface that extends linearly between the lower side and one side in the third direction D3 when seen in the second direction D2. An end portion of the second inner surface portion 43c on one side in the third direction D3 is connected to an end portion of the first inner surface portion 43a on the other side in the third direction D3. In this embodiment, a portion at which the first inner surface portion 43a and the second inner surface portion 43c are connected is located at a center portion of the first inner surface 43 in the third direction D3. In this embodiment, the first inner surface 43 has a V-shape that protrudes downward when seen in the second direction D2. The second inner surface portion 43c may be a curved surface that extends in a curved shape between the lower side and one side in the third direction D3 when seen in the second direction D2.

The first inner surface 43 may not have one of the first inner surface portion 43a and the second inner surface portion 43c. For example, when the first inner surface 43 does not have the second inner surface portion 43c, preferably, the first inner surface portion 43a is an inclined surface connected to each of an end portion of the first inner surface 43 on one side (the +D3 side) in the third direction D3 and an end portion of the first inner surface 43 on the other side (the −D3 side) in the third direction D3. Similarly, for example, when the first inner surface 43 does not have the first inner surface portion 43a, preferably, the second inner surface portion 43c is an inclined surface connected to each of an end portion of the first inner surface 43 on the other side in the third direction D3 and an end portion of the first inner surface 43 on one side in the third direction D3.

As shown in FIG. 2, the connection portion 46 has a plate shape that is located downward, that is, on the other side (the −D1 side) in the first direction D1, toward one side (the +D2 side) in the second direction D2. An end portion of the connection portion 46 on the other side (the −D2 side) in the second direction D2 is connected to an end portion of the bonding portion 41 on one side in the second direction D2.

The terminal portion 47 has a plate shape that extends to one side in the second direction D2 from an end portion of the connection portion 46 on one side (the +D2 side) in the second direction D2. A plate surface of the terminal portion 47 faces in the up-down direction. The terminal portion 47 is bonded to the electrode terminal 71 by a bonding material (not shown). Thus, the connector member 40 is electrically connected to the electrode terminal 71. In this embodiment, the electrode terminal 71 is, for example, a source terminal used for connecting to the outside of the semiconductor device 10. The electrode terminal 71 is disposed at an interval from the lead frame 30 in the second direction D2. The electrode terminal 71 is made of a metal. The electrode terminal 71 has conductivity. As described above, the connector member 40 is electrically connected to the semiconductor chip 20. Therefore, the semiconductor chip 20 is electrically connected to the electrode terminal 71.

As shown in FIG. 1, the second connector member 70 has a plate shape that extends in the second direction D2. The second connector member 70 has conductivity. In this embodiment, the second connector member 70 is made of copper. The second connector member 70 is manufactured by, for example, pressing a copper plate. One end of the second connector member 70 is bonded to the third electrode 24 of the semiconductor chip 20 by a bonding material (not shown). The other end of the second connector member 70 is bonded to the electrode terminal 72 by a bonding material (not shown). Thus, the semiconductor chip 20 and the electrode terminal 72 are electrically connected to each other via the second connector member 70. In this embodiment, the electrode terminal 72 is, for example, a gate terminal used for connecting to the outside of the semiconductor device 10. The electrode terminal 72 is disposed at an interval from each of the lead frame 30 and the electrode terminal 71. The electrode terminal 72 is made of a metal. The electrode terminal 72 has conductivity.

The resin part 80 shown in FIGS. 2 and 3 covers the semiconductor chip 20, a portion of the lead frame 30 other than a surface thereof that faces downward, the connector member 40, the second connector member 70, and a portion of each of the electrode terminals 71 and 72 other than a surface thereof that faces downward. The resin part 80 is bonded and fixed to the semiconductor chip 20, the portion of the lead frame 30 other than the surface thereof that faces downward, the connector member 40, the second connector member 70, and the portion of each of the electrode terminals 71 and 72 other than the surface that faces downward. The resin part 80 insulates each of the parts constituting the semiconductor device 10 from one another. Also the resin part 80 seals each of the parts constituting the semiconductor device 10 from external air. Thus, it is possible to curb the parts constituting the semiconductor device 10 deteriorating due to corrosion or the like. The resin part 80 may be made of, for example, a known epoxy resin, an ultraviolet curable resin, a thermosetting resin, or the like, but is not limited thereto. In this embodiment, the resin part 80 is made of an epoxy resin.

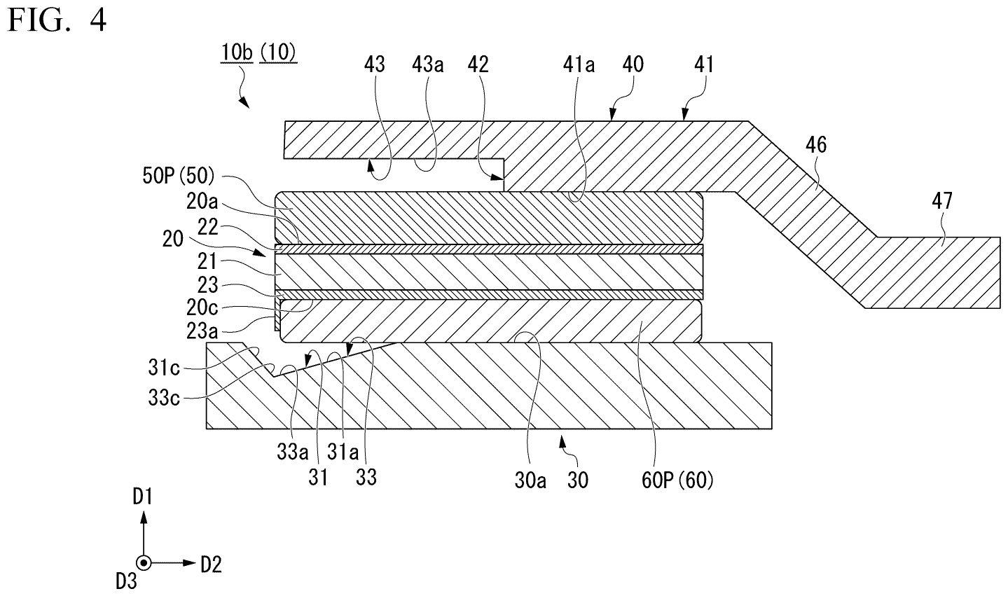

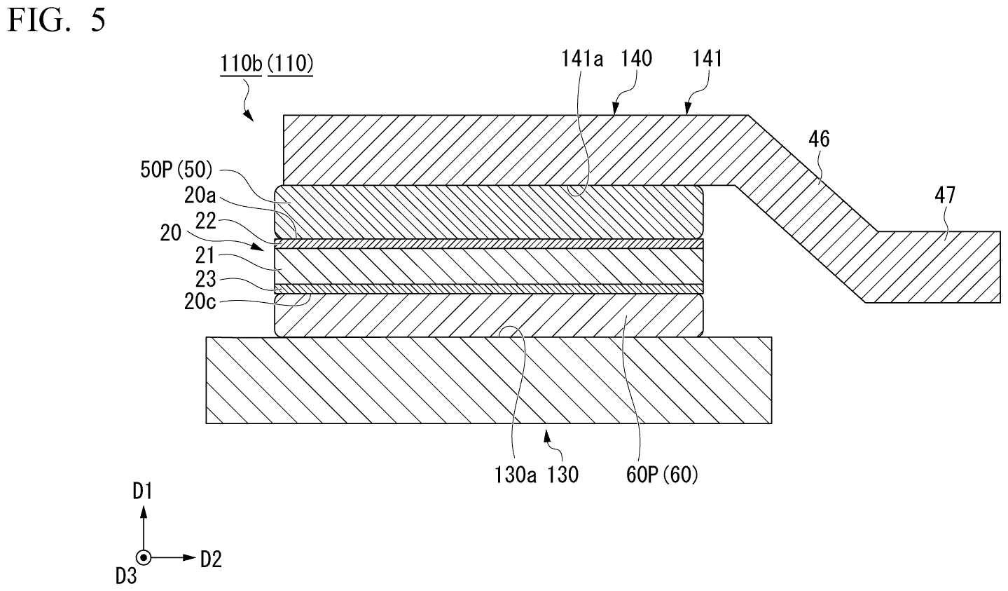

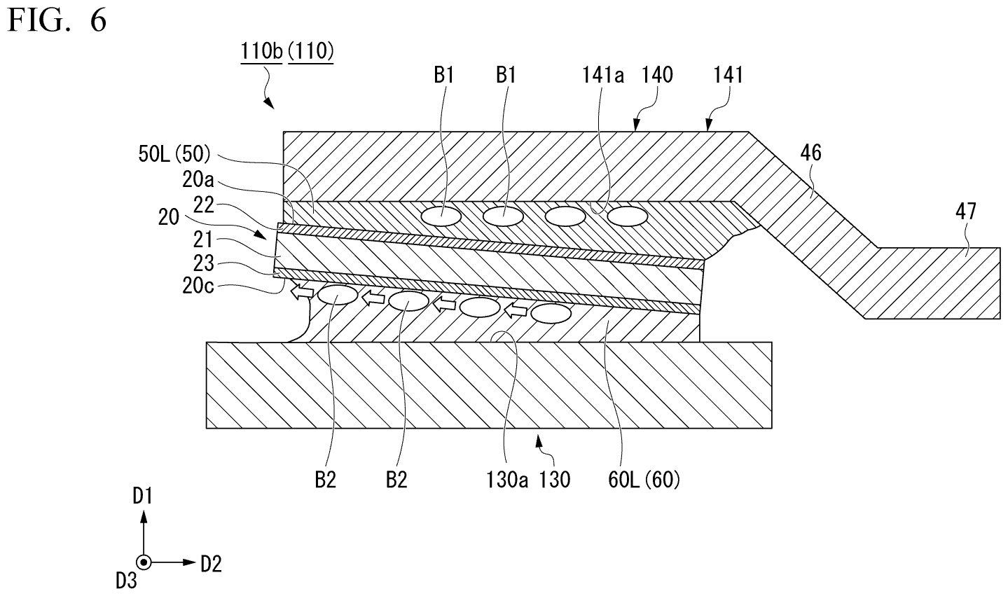

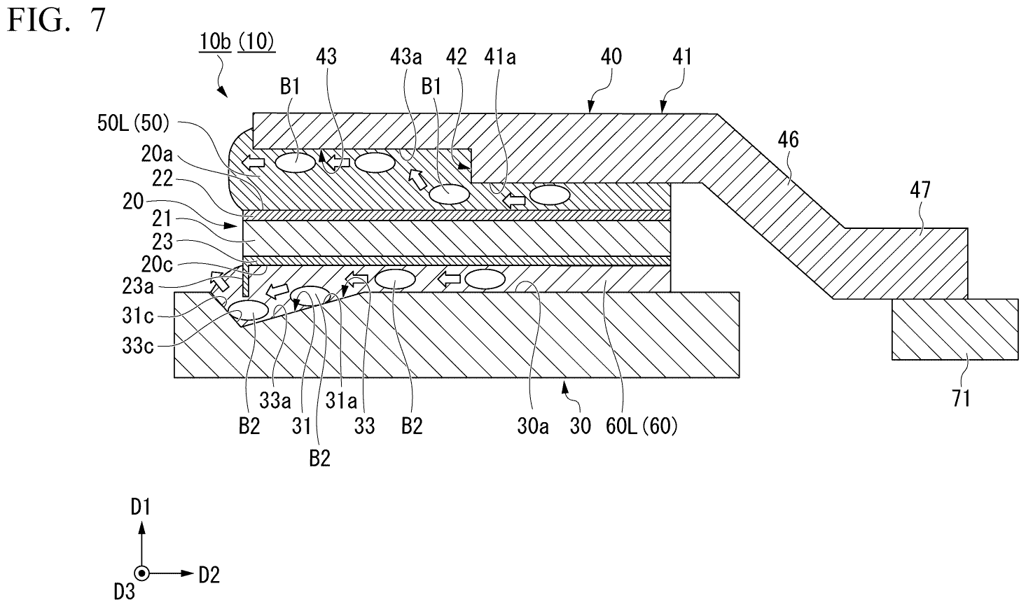

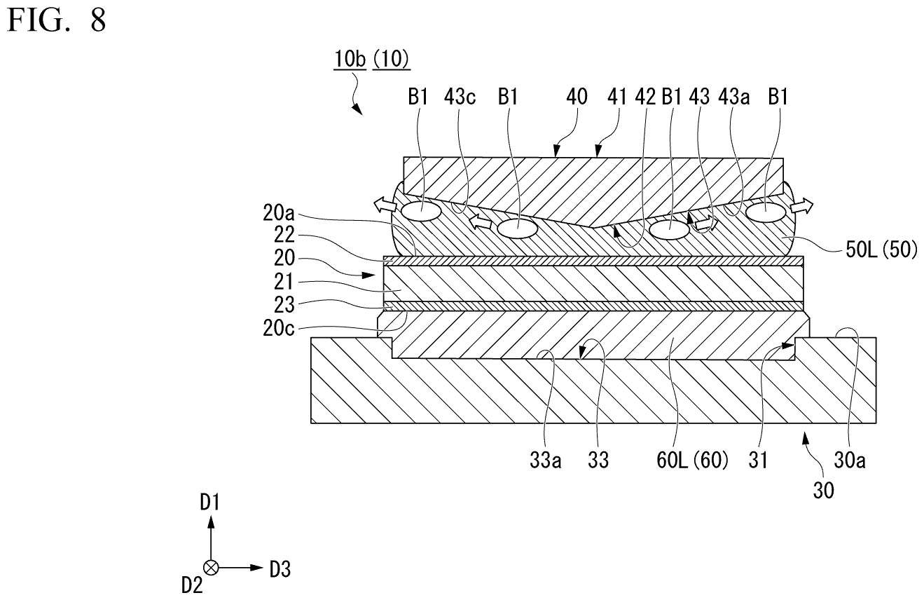

FIG. 4 is a first cross-sectional view showing a manufacturing process of the semiconductor device 10 of this embodiment. FIG. 5 is a first cross-sectional view showing a manufacturing process of a semiconductor device 110 of the comparative example. FIG. 6 is a second cross-sectional view showing the manufacturing process of the semiconductor device 110 of the comparative example. FIG. 7 is a second cross-sectional view showing the manufacturing process of the semiconductor device 10 of this embodiment. FIG. 8 is a third cross-sectional view showing the manufacturing process of the semiconductor device 10 of this embodiment.

Next, the manufacturing process of the semiconductor device 10 of this embodiment will be described. The manufacturing process of the semiconductor device 10 of this embodiment includes an application process P01 in which a paste-like first bonding material 50P is applied to a first chip surface 20a of a semiconductor chip 20 and a paste-like second bonding material 60P is applied to a second chip surface 20c, a reflow process P02 in which the first bonding material 50P and the second bonding material 60P are reflowed, and a resin part molding process P03 in which a resin part 80 is molded. In the following description, the term “worker or the like” includes workers who perform a work of each of the processes, assembly equipment, and the like. The work of each of the processes may be performed by only workers, may be performed by only assembly equipment, or may be performed by both workers and assembly equipment.

In the application process P01, the worker or the like first applies the paste-like first bonding material 50P to the first chip surface 20a of the semiconductor chip 20 and then applies the paste-like second bonding material 60P to the second chip surface 20c, as shown in FIG. 4. In this embodiment, each of the first bonding material 50P and the second bonding material 60P is made of flux and solder particles containing tin and lead. In this embodiment, the flux is, for example, rosin. The flux serves to increase wettability between the semiconductor chip 20, the lead frame 30, and the connector member 40 and the molten first bonding material 50L and second bonding material 60L.

Next, the worker or the like places the semiconductor chip 20 on the second bonding surface 30a of the lead frame 30. Thus, the second bonding material 60P comes into contact with both the second chip surface 20c and the second bonding surface 30a. Next, the worker or the like places the connector member 40 on the first chip surface 20a of the semiconductor chip 20. Thus, the first bonding material 50P comes into contact with both the first chip surface 20a and the first bonding surface 41a. When the worker or the like places the connector member 40 on the first chip surface 20a, the application process P01 is completed. In the following description, the semiconductor device 10 at the time when the application process P01 is completed may be referred to as a semiconductor device 10b before bonding.

In the reflow process P02, the first bonding material 50P and the second bonding material 60P are reflowed. Thus, the semiconductor chip 20 is bonded to the lead frame 30, and the connector member 40 is bonded to the semiconductor chip 20. In the reflow process P02, the worker or the like heats the semiconductor device 10b before bonding in a heating furnace (not shown), for example, in a vacuum, to melt the paste-like first bonding material 50P and the paste-like second bonding material 60P, then removes the semiconductor device 10b before bonding from the heating furnace and cools it to solidify the liquid first bonding material 50L and second bonding material 60L, bonds the semiconductor chip 20 to the lead frame 30, and thus bonds the connector member 40 to the semiconductor chip 20.

In the semiconductor device 110 of the comparative example shown in FIG. 5, the second recessed portion is not provided in the second bonding surface 130a of the lead frame 130. Furthermore, in the semiconductor device 110, the first recessed portion is not provided in the first bonding surface 141a of the bonding portion 141 of the connector member 140. Therefore, in the reflow process P02 of the semiconductor device 110b before bonding of the comparative example, as shown in FIG. 6, the molten liquid first bonding material 50L tends to flow toward the connection portion 46, and the semiconductor chip 20 is pulled by the liquid first bonding material 50L flowing toward the connection portion 46. Thus, the semiconductor chip 20 is inclined such that an orientation of the first chip surface 20a faces from the upper side to one side (the +D2 side) in the second direction D2. In this state, when the first bonding material 50L and the second bonding material 60L are solidified, the semiconductor chip 20 is bonded to the lead frame 30 and the connector member 40 in an inclined state. In this case, an amount of second bonding material 60L at a portion of second chip surface 20c on the other side (the −D2 side) in second direction D2 is likely to be insufficient. Therefore, there is a risk that an adhesive strength between the portion of the second chip surface 20c on the other side (the −D2 side) in the second direction D2 and the second bonding surface 30a may decrease. Therefore, a bonding strength between the semiconductor chip 20 and the lead frame 30 may decrease.

In addition, in the reflow process P02, when the flux, water, and the like not shown contained in each of the paste-like first bonding material 50P and the paste-like second bonding material 60P evaporate, voids B1 which are air gaps are generated inside the liquid first bonding material 50L, and voids B2 which are air gaps are generated inside the liquid second bonding material 60L. In the reflow process P02, the voids B2 tend to accumulate in a portion of the second bonding material 60L on the other side (the −D2 side) in the second direction D2. As described above, since the reflow of the first bonding material 50P and the second bonding material 60P is performed in a vacuum, the voids B1 move to an end portion of the first bonding material 50L and are released to the outside of the first bonding material 50L. Similarly, the voids B2 move to an end portion of the second bonding material 60L and are released to the outside of the second bonding material 60L. However, in the reflow process P02, when the semiconductor chip 20 is in the inclined state as described above, a gap between the portion of the semiconductor chip 20 on the other side (the −D2 side) in the second direction D2 and the connector member 40 in the up-down direction becomes smaller. Therefore, since it is difficult for the voids B1 to move to the other side in the second direction D2, it is difficult to be released from the end portion of the first bonding material 50L on the other side in the second direction D2. As a result, there is a risk that a large number of voids B1 will remain inside the hardened first bonding material 50. As described above, since the voids B1 and B2 are air gaps, electrical resistivity of the voids B1 and B2 is greater than electrical resistivity of the solder. Thus, when a large number of voids B1 remain inside the first bonding material 50, electrical resistance of the first bonding material 50 increases, and thus an amount of current that can be passed therethrough decreases. Therefore, an operation region of the semiconductor device 110 becomes narrower. In the semiconductor device 110 of the comparative example, the voids B2 are released from the end portion of the second bonding material 60L on the other side in the second direction D2.

On the other hand, in the semiconductor device 10 of this embodiment, the first recessed portion 42 is provided in the first bonding surface 41a of the bonding portion 41 of the connector member 40, as described above. Therefore, in the reflow process P02, as shown in FIG. 7, since the molten liquid first bonding material 50L flows into the inside of the first recessed portion 42, it is possible to curb the first bonding material 50L flowing toward the connection portion 46. Thus, it is possible to curb the semiconductor chip 20 being in the inclined state. Therefore, since it is possible to curb a shortage of the amount of second bonding material 60L at the portion of the second chip surface 20c on the other side (the −D2 side) in the second direction D2, it is possible to curb a decrease in the bonding strength between the semiconductor chip 20 and the lead frame 30.

In addition, in this embodiment, since the first recessed portion 42 is provided in the first bonding surface 41a, the gap between the first inner surface 43 and the first chip surface 20a in the up-down direction can be increased. Therefore, the voids B1 easily move to the inside of the first recessed portion 42. As described above, since the voids B1 are air gaps, a specific gravity of the voids B1 is smaller than a specific gravity of the solder. Therefore, in the reflow process P02, the voids B1 that have moved into the inside of the first recessed portion 42 moves along the first inner surface 43 to the other side (the −D2 side) in the second direction D2. As described above, the first recessed portion 42 is open to the other side in the second direction D2. Thus, the voids B1 that have moved to the end portion of the first bonding material 50L on the other side in the second direction D2 are released to the outside of the first bonding material 50L from the end portion of the first bonding material 50L on the other side in the second direction D2. Therefore, in this embodiment, it is possible to suitably reduce the number of voids B1 remaining inside the first bonding material 50. Thus, it is possible to suitably curb an increase in the electrical resistance of the first bonding material 50.

As described above, the first inner surface 43 has the first inner surface portion 43a. Therefore, as shown in FIG. 8, in the reflow process P02, some of the voids B1 that have moved into the inside of the first recessed portion 42 tend to move along the first inner surface portion 43a to one side (the +D3 side) in the third direction D3. In other words, the first inner surface portion 43a guides the movement of the voids B1 to one side in the third direction D3. Thus, the voids B1 move to the end portion of the first bonding material 50L on one side in the third direction D3, and are released to the outside of the first bonding material 50L from the end portion of the first bonding material 50L on the one side in the third direction D3. Therefore, in this embodiment, it is possible to more suitably reduce the number of voids B1 remaining inside the first bonding material 50. Thus, it is possible to more suitably curb an increase in the electrical resistance of the first bonding material 50.

Also, as described above, the first inner surface 43 has the second inner surface portion 43c. Therefore, in the reflow process P02, some of the voids B1 that have moved into the inside of the first recessed portion 42 tend to move along the second inner surface portion 43c to the other side (the −D3 side) in the third direction D3. In other words, the second inner surface portion 43c guides the movement of the voids B1 to the other side in the third direction D3. Thus, the voids B1 move to the end portion of the first bonding material 50L on the other side in the third direction D3, and are released to the outside of the first bonding material 50L from the end portion of the first bonding material 50L on the other side in the third direction D3. Therefore, in this embodiment, it is possible to more suitably reduce the number of voids B1 remaining inside the first bonding material 50. As a result, it is possible to suitably curb an increase in the electrical resistance of the first bonding material 50.

As shown in FIG. 7, in this embodiment, a burr 23a that protrudes downward is formed on an edge portion of the second electrode 23 on the other side (the −D2 side) in the second direction D2. The burr 23a is formed, for example, when the semiconductor chip 20 is diced. A dimension of the burr 23a in the up-down direction is about 15 μm at maximum. Although not shown in the drawings, when the second recessed portion 31 is not provided in the second bonding surface 30a, a gap between the burr 23a and the second bonding surface 30a in the up-down direction becomes smaller, and thus it is difficult for the voids B2 to move inside the second bonding material 60L to the other side in the second direction D2. Therefore, since it is difficult to release the voids B2 to the outside of the second bonding material 60L, there is a risk that a large number of voids B2 will remain inside the second bonding material 60. On the other hand, in this embodiment, the second recessed portion 31 is provided in the second bonding surface 30a. Therefore, in the reflow process P02, the molten liquid second bonding material 60L flows into the inside of the second recessed portion 31. As described above, the second recessed portion 31 overlaps an edge portion of the semiconductor chip 20 on the other side in the second direction D2 when seen in the up-down direction. Thus, even when the burr 23a is formed on the second electrode 23, the gap between the burr 23a and the second inner surface 33 in the up-down direction can be increased, and thus, the voids B2 can move around the lower side of the burr 23a toward the end portion of the second bonding material 60L on the other side in the second direction D2. As a result, the voids B2 are released to the outside of the second bonding material 60L from the end portion of the second bonding material 60L on the other side in the second direction D2. Therefore, in this embodiment, it is possible to suitably reduce the number of voids B2 remaining inside the second bonding material 60. Thus, it is possible to suitably curb an increase in the electrical resistance of the second bonding material 60. As described above, in this embodiment, it is possible to suitably curb an increase in the electrical resistance of the first bonding material 50. As a result, since it is possible to curb an amount of current that can be passed through the semiconductor device 10 decreasing, it is possible to curb the operation region of the semiconductor device 10 becoming narrower.

Next, the worker or the like causes the paste-like first bonding material 50P and the paste-like second bonding material 60P to reflow, then removes the semiconductor device 10b before bonding from the heating furnace and cools it. Thus, the liquid first bonding material 50L and the liquid second bonding material 60L are solidified, the semiconductor chip 20 is bonded to the lead frame 30, and the connector member 40 is bonded to the semiconductor chip 20. When the semiconductor chip 20 is bonded to the lead frame 30, and the connector member 40 is bonded to the semiconductor chip 20, the reflow process P02 is completed.

In the resin part molding process P03, the worker or the like molds the resin part 80. In this embodiment, as shown in FIGS. 2 and 3, in accordance with a molding method such as transfer molding, the semiconductor chip 20, the portion of the lead frame 30 other than the surface that faces downward, the connector member 40, the second connector member 70, and the portion of each of the electrode terminals 71 and 72 other than the surface that faces downward are covered with the resin part 80, and then the resin part 80 is hardened, for example, by heating to form the resin part 80. As described above, the resin part 80 is bonded and fixed to the semiconductor chip 20, the portion of the lead frame 30 other than the surface that faces downward, the connector member 40, the second connector member 70, and the portion of each of the electrode terminals 71 and 72 other than the surface that faces downward. The resin part molding process P03 is completed when the worker or the like hardens the resin part 80. When the resin part molding process P03 is completed, the manufacturing process of the semiconductor device 10 is completed, and the semiconductor device 10 shown in FIGS. 2 and 3 is manufactured.

According to this embodiment, the semiconductor device 10 includes a semiconductor chip 20 having a first chip surface 20a that faces upward, that is, one side (the +D1 side) in the first direction D1 and a second chip surface 20c that faces downward, that is, the other side (the −D1 side) in the first direction D1, a connector member 40 having a bonding portion 41 that faces the first chip surface 20a in the first direction D1 and a connection portion 46 connected to the bonding portion 41, and a lead frame 30 that faces the second chip surface 20c in the first direction D1. The connection portion 46 is connected to an end portion of the bonding portion 41 on one side (the +D2 side) in the second direction D2 and is located downward toward one side in the second direction D2, the bonding portion 41 has the first bonding surface 41a that is bonded to the first chip surface 20a by the first bonding material 50, and the lead frame 30 has the second bonding surface 30a that is bonded to the second chip surface 20c by the second bonding material 60. The first bonding surface 41a has the first recessed portion 42 that is recessed upward and is open to the other side (the −D2 side) in the second direction, and part of the first bonding material 50 is accommodated inside the first recessed portion 42. Therefore, as described above, in the reflow process P02, since the molten liquid first bonding material 50L flows into the inside of the first recessed portion 42, it is possible to curb the first bonding material 50L flowing toward the connection portion 46. Therefore, it is possible to curb the semiconductor chip 20 being bonded to the lead frame 30 and the connector member 40 in an inclined state. Furthermore, as described above, since it is possible to curb a shortage of the amount of second bonding material 60L in the portion of the second chip surface 20c on the other side in the second direction D2, it is possible to curb a decrease in the bonding strength between the semiconductor chip 20 and the lead frame 30.

Further, in this embodiment, since the first bonding surface 41a has the first recessed portion 42 that is open to the other side (the −D2 side) in the second direction D2, even when the semiconductor chip 20 is in the inclined state in the reflow process P02, it is possible to curb a gap between the portion of the first chip surface 20a on the other side (the −D2 side) in the second direction D2 and the first inner surface 43 in the up-down direction becoming too small. Thus, in the reflow process P02, the voids B1 generated inside the first bonding material 50L can be suitably moved to the end portion of the first bonding material 50L on the other side in the second direction D2. Therefore, the voids B1 can be suitably released to the outside of the first bonding material 50L from the end portion of the first bonding material 50L on the other side in the second direction D2. Therefore, the number of voids B1 remaining inside the first bonding material 50 can be suitably reduced, and thus an increase in the electrical resistance of the first bonding material 50 can be suitably curbed. As a result, since it is possible to curb the current that can be passed through the semiconductor device 10 decreasing, it is possible to curb the operation region of the semiconductor device 10 becoming narrower.

According to this embodiment, the second ratio R2 which is the ratio of the dimension L12 of the first recessed portion 42 in the second direction to the dimension Lj2 of the bonding portion 41 in the second direction D2 is 40% or more and 60% or less. In the reflow process P02, the voids B1 generated inside the liquid first bonding material 50L tend to accumulate near a center portion of the first bonding material 50L. On the other hand, in this embodiment, since the second ratio R2 is 40% or more and 60% or less, the end portion of the first recessed portion 42 on one side (the +D2 side) in the second direction D2 can be disposed near the center portion of the first bonding material 50L. Thus, in the reflow process P02, since the voids B1 inside the first bonding material 50L can be preferably moved to the inside of the first recessed portion 42, the number of voids B1 released from the first bonding material 50L can be more preferably increased. Therefore, since the number of voids B1 remaining inside the first bonding material 50 can be more suitably reduced, the increase in the electrical resistance of the first bonding material 50 can be more suitably curbed.

According to this embodiment, the first recessed portion 42 is open on both sides in the third direction D3, and the first inner surface 43 which is a surface that faces downward, that is, the other side (the −D1 side) in the first direction D1 among the inner surfaces of the first recessed portion 42 has the first inner surface portion 43a that is located downward as it goes from an end portion of the first inner surface 43 on one side (the +D3 side) in the third direction D3 to the other side (the −D3 side) in the third direction D3. Therefore, as described above, in the reflow process P02, the voids B1 generated inside the molten liquid first bonding material 50L tend to move along the first inner surface portion 43a to one side in the third direction D3. Thus, it is possible to suitably increase the number of voids B1 that are released to the outside of the first bonding material 50L from the end portion of the first bonding material 50L on the one side in the third direction D3. Therefore, the number of voids B1 remaining inside the first bonding material 50 can be more suitably reduced, and the increase in the electrical resistance of the first bonding material 50 can be more suitably curbed.

According to this embodiment, the first inner surface 43 has the second inner surface portion 43c that is located downward, that is, on the other side (the −D1 side) in the first direction D1, as it goes from the end portion of the first inner surface 43 on the other side (the −D3 side) in the third direction D3 to one side (the +D3 side) in the third direction D3, and an end portion of the second inner surface portion 43c on one side in the third direction D3 is connected to an end portion of the first inner surface portion 43a on the other side in the third direction D3. Therefore, as described above, in the reflow process P02, the voids B1 generated inside the molten liquid first bonding material 50L tend to move along the second inner surface portion 43c to the other side in the third direction D3. Thus, it is possible to suitably increase the number of voids B1 that are released to the outside of the first bonding material 50L from the end portion of the first bonding material 50L on the other side in the third direction D3. Therefore, since the number of voids B1 remaining inside the first bonding material 50 can be more suitably reduced, the increase in the electrical resistance of the first bonding material 50 can be more suitably curbed.

According to this embodiment, the first ratio R1 which is the ratio of the dimension L11 of the first recessed portion 42 in the up-down direction, that is, the first direction D1 to the dimension Lj1 of the bonding portion 41 in the up-down direction is 40% or more and 60% or less. When the first ratio R1 is smaller than 40%, a volume of the first recessed portion 42 becomes too small, and thus it is difficult for the molten liquid first bonding material 50L to flow into the inside of the first recessed portion 42 in the reflow process P02. Therefore, since it is difficult to curb the first bonding material 50L flowing toward the connection portion 46, it is difficult to curb the semiconductor chip 20 being bonded to the lead frame 30 and the connector member 40 in the inclined state. Furthermore, when the first ratio R1 is greater than 60%, a dimension of the side surface 41c (refer to FIG. 3) of the bonding portion 41 in the up-down direction that faces in the third direction D3 becomes too small. Therefore, in the reflow process P02, the first bonding material 50L leaking out of the first recessed portion 42 in the third direction D3 is likely to adhere to a surface 41d of the connector member 40 that faces upward (refer to FIG. 3). As a result, an area in which the surface 41d of the connector member 40 that faces upward and the resin part 80 are directly bonded to each other is reduced, and thus the adhesive strength between the connector member 40 and the resin part 80 may be reduced.

On the other hand, in this embodiment, since the first ratio R1 is 40% or more, it is possible to curb the volume of the first recessed portion 42 becoming too small. Therefore, in the reflow process P02, it is possible to more effectively curb the semiconductor chip 20 being bonded to the lead frame 30 and the connector member 40 in the inclined state. In addition, in this embodiment, since the first ratio R1 is 60% or less, it is possible to curb the dimension of the side surface 41c in the first direction D1 becoming too small. Thus, it is possible to properly curb the first bonding material 50 adhering to the surface 41d of the connector member 40 that faces upward. Therefore, it is possible to curb the area in which the surface 41d of the connector member 40 that faces upward and the resin part 80 are directly bonded to each other being reduced, and thus it is possible to curb the decrease in the adhesive strength between the connector member 40 and the resin part 80.

According to this embodiment, the second recessed portion 31 recessed downward, that is, to the other side (the −D1 side) in the first direction D1 is provided in the second bonding surface 30a, and when seen in the first direction D1, the second recessed portion 31 overlaps the edge portion of the semiconductor chip 20 on the other side (the −D2 side) in the second direction D2, and part of the second bonding material 60 is accommodated inside the second recessed portion 31. As described above, in the reflow process P02, the voids B2 tend to accumulate in a portion of the second bonding material 60L on the other side (the −D2 side) in the second direction D2. In this embodiment, since the second recessed portion 31 can be disposed to be opposite to a portion of the semiconductor chip 20 on the other side in the second direction D2 in the up-down direction, in the reflow process P02, the voids B2 that have accumulated in the portion of the second bonding material 60L on the other side in the second direction D2 can be suitably released from an end portion of the second bonding material 60L on the other side in the second direction D2 via the second bonding material 60L that has flowed into the inside of the second recessed portion 31. Therefore, since the number of voids B2 remaining inside the second bonding material 60 can be suitably reduced, the increase in the electrical resistance of the second bonding material 60 can be curbed. Thus, since it is possible to more effectively curb the current that can be passed through the semiconductor device 10 decreasing, it is possible to more effectively curb the operation region of the semiconductor device 10 being narrowed.

According to this embodiment, the maximum dimension L2max of the second recessed portion 31 in the first direction D1 is 15 μm or more. Therefore, as described above, even when the burr 23a is formed on the second electrode 23, a gap between the burr 23a and the second inner surface 33 in the up-down direction can be increased. Therefore, as described above, in the reflow process P02, the voids B2 can move around the lower side of the burr 23a toward the end portion of the second bonding material 60L on the other side (the −D2 side) in the second direction D2. Thus, the voids B2 can be suitably released to the outside of the second bonding material 60L from the end portion of the second bonding material 60L on the other side in the second direction D2. Therefore, since the number of voids B2 remaining inside the second bonding material 60 can be suitably reduced, the increase in the electrical resistance of the second bonding material 60 can be more suitably curbed.

According to this embodiment, the second recessed portion 31 has the first portion 31a that overlaps the semiconductor chip 20 when seen in the first direction D1, and the third ratio R3 which is the ratio of the dimension Lp1 of the first portion 31a in the second direction D2 to the dimension Lc2 of the semiconductor chip 20 in the second direction D2 is 25% or more and 33% or less. When the third ratio is smaller than 25%, the dimension of the second recessed portion 31 in the second direction D2 becomes too small, and thus it is difficult for the voids B2 to move into the inside of the second recessed portion 31 in the reflow process P02. Therefore, there is a risk that the number of voids B2 remaining inside the second bonding material 60 will increase. Furthermore, when the third ratio R3 is greater than 33%, a volume of the second recessed portion 31 becomes too large, and the volume of the second bonding material 60 required to fill the second recessed portion 31 increases. Therefore, material cost of the second bonding material 60 increases, and thus manufacturing cost of the semiconductor device 10 increases.

On the other hand, in this embodiment, since the third ratio R3 is 25% or more, it is possible to curb the dimension of the second recessed portion 31 in the second direction D2 becoming too small. Thus, in the reflow process P02, the number of voids B2 that move into the inside of the second recessed portion 31 can be increased. Therefore, the number of voids B2 released to the outside of the second bonding material 60L can be increased, and thus the number of voids B2 remaining inside the second bonding material 60 can be more suitably reduced. In addition, in this embodiment, since the third ratio R3 is 33% or less, it is possible to curb the volume of the second recessed portion 31 becoming too large. Thus, it is possible to curb an increase in the volume of the second bonding material 60 required to fill the second recessed portion 31. Therefore, it is possible to curb an increase in the material cost of the second bonding material 60, and thus it is possible to curb an increase in the manufacturing cost of the semiconductor device 10.

According to this embodiment, the second recessed portion 31 has the second portion 31c located on the other side (the −D2 side) in the second direction D2 with respect to the semiconductor chip 20, and the dimension Lp2 of the second portion 31c in the second direction D2 is 0.05 mm or more and 0.15 mm or less. When the dimension Lp2 of the second portion 31c in the second direction D2 is smaller than 0.05 mm, since a gap between the fourth inner surface portion 33c and the semiconductor chip 20 is too narrow, it becomes difficult for the voids B2 that have moved to the inside of the second recessed portion 31 to be released to the outside of the second bonding material 60L. Furthermore, when the dimension Lp2 of the second portion 31c in the second direction D2 is greater than 0.15 mm, a distance between the second recessed portion 31 and the end portion of the lead frame 30 on the other side in the second direction D2 becomes too short. Therefore, the second bonding material 60 leaking out of the second recessed portion 31 to the other side in the second direction D2 is more likely to adhere to the surface 30c of the lead frame 30 that faces downward (refer to FIG. 2). In this case, the second bonding material 60 containing lead is exposed to the outside of the resin part 80, and thus environmental characteristics of the semiconductor device 10 are impaired.

On the other hand, in this embodiment, since the dimension Lp2 of the second portion 31c in the second direction D2 is 0.05 mm or more, it is possible to curb the gap between the fourth inner surface portion 33c and the semiconductor chip 20 becoming too narrow. Thus, the voids B2 that have moved to the inside of the second recessed portion 31 can be suitably released to the outside of the second bonding material 60L from the end portion of the second bonding material 60L on the other side in the second direction D2. Therefore, the increase in the electrical resistance of the second bonding material 60 can be more suitably curbed. In addition, in this embodiment, since the dimension Lp2 of the second portion 31c in the second direction D2 is 0.15 mm or less, it is possible to curb the distance between the second recessed portion 31 and the end portion of the lead frame 30 on the other side in the second direction D2 becoming too short. Thus, it is possible to curb the second bonding material 60 adhering to the surface 30c of the lead frame 30 that faces downward. Therefore, it is possible to curb the environmental characteristics of the semiconductor device 10 being impaired.

According to this embodiment, the dimension L23 of the second recessed portion 31 in the third direction D3 is equal to or smaller than the dimension Lc3 of the semiconductor chip 20 in the third direction D3. Therefore, both ends of the second recessed portion 31 in the third direction D3 can be easily disposed close to the edge portion of the semiconductor chip 20 in the third direction D3. Thus, since it is possible to curb the gap between both ends of the second recessed portion 31 in the third direction D3 and the semiconductor chip 20 becoming too large, it is possible to curb the second bonding material 60L leaking from the end portion of the second recessed portion 31 in the third direction D3 to the second bonding surface 30a. Therefore, it is possible to curb the area in which the second bonding surface 30a and the resin part 80 are directly bonded decreasing, and thus the decrease in the adhesive strength between the lead frame 30 and the resin part 80 can be curbed.

According to this embodiment, the second inner surface 33 which is a surface that faces upward, that is, one side (the +D1 side) in the first direction D1, among the inner surfaces of the second recessed portion 31, has a third inner surface portion 33a located downward, that is, on the other side (the −D1 side) in the first direction D1 as it goes from the end portion of the second inner surface 33 on one side (the +D2 side) in the second direction D2 to the other side (the −D2 side) in the second direction D2, and a fourth inner surface portion 33c located downward as it goes from an end portion of the second inner surface 33 on the other side in the second direction D2 to one side in the second direction D2, and an end portion of the fourth inner surface portion 33c on one side in the second direction D2 is connected to an end portion of the third inner surface portion 33a on the other side in the second direction D2. Therefore, in the reflow process P02, the voids B2 generated inside the molten liquid second bonding material 60L move along the third inner surface portion 33a into the inside of the second recessed portion 31 and then move along the fourth inner surface portion 33c to the other side in the second direction D2. Thus, since the voids B2 tend to move toward the end portion of the second bonding material 60L on the other side in the second direction D2, the number of voids B2 released from the end portion of the second bonding material 60L on the other side in the second direction D2 to the outside of the second bonding material 60L can be more preferably increased. Therefore, the number of voids B2 remaining inside the second bonding material 60 can be more effectively reduced, and thus the increase in the electrical resistance of the second bonding material 60 can be more effectively curbed.

According to the embodiment described above, since the first recessed portion that is recessed on one side in the first direction and is open to the other side in the second direction is provided in the first bonding surface, it is possible to provide a semiconductor device that can curb the semiconductor chip being bonded to the lead frame and the connector member in an inclined state.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor chip having a first chip surface configured to face one side in a first direction and a second chip surface configured to face the other side in the first direction;
a connector member having a bonding portion configured to face the first chip surface in the first direction and a connection portion connected to the bonding portion; and
a lead frame configured to face the second chip surface in the first direction,
wherein the connection portion is connected to an end portion of the bonding portion on one side in a second direction perpendicular to the first direction, and is located on the other side in the first direction toward one side in the second direction,
the bonding portion has a first bonding surface bonded to the first chip surface by a first bonding material,
the lead frame has a second bonding surface bonded to the second chip surface by a second bonding material,
a first recessed portion that is recessed on one side in the first direction and is open to the other side in the second direction is provided in the first bonding surface,
part of the first bonding material is accommodated inside the first recessed portion, and
a dimension of the first recessed portion in the second direction is 40% or more and 60% or less of a dimension of the bonding portion in the second direction.

2. The semiconductor device according to claim 1, wherein the first recessed portion is open on both sides in a third direction that is a direction perpendicular to both the first direction and the second direction, and
a first inner surface which is a surface that faces the other side in the first direction, among inner surfaces of the first recessed portion, has a first inner surface portion located on the other side in the first direction as it goes from an end portion of the first inner surface on one side in the third direction to the other side in the third direction.

3. The semiconductor device according to claim 2, wherein the first inner surface has a second inner surface portion located on the other side in the first direction as it goes from an end portion of the first inner surface on the other side in the third direction to one side in the third direction, and
an end portion of the second inner surface portion on one side in the third direction is connected to an end portion of the first inner surface portion on the other side in the third direction.

4. The semiconductor device according to claim 1, wherein a dimension of the first recessed portion in the first direction is 40% or more and 60% or less of a dimension of the bonding portion in the first direction.

5. The semiconductor device according to claim 1, wherein a second recessed portion recessed to the other side in the first direction is provided in the second bonding surface,
when seen in the first direction, the second recessed portion overlaps an edge portion of the semiconductor chip on the other side in the second direction, and
part of the second bonding material is accommodated inside the second recessed portion.

6. The semiconductor device according to claim 5, wherein a maximum dimension of the second recessed portion in the first direction is 15 μm or more.

7. The semiconductor device according to claim 5, wherein the second recessed portion has a first portion that overlaps the semiconductor chip when seen in the first direction, and
a dimension of the first portion in the second direction is 25% or more and 33% or less of a dimension of the semiconductor chip in the second direction.

8. The semiconductor device according to claim 5, wherein the second recessed portion has a second portion located on the other side in the second direction with respect to the semiconductor chip, and
a dimension of the second portion in the second direction is 0.05 mm or more and 0.15 mm or less.

9. The semiconductor device according to claim 5, wherein a dimension of the second recessed portion in a third direction perpendicular to both the first direction and the second direction is equal to or smaller than a dimension of the semiconductor chip in the third direction.

10. The semiconductor device according to claim 5, wherein a second inner surface which is a surface configured to face one side in the first direction, among inner surfaces of the second recessed portion, has a third inner surface portion located on the other side in the first direction as it goes from an end portion of the second inner surface on one side in the second direction to the other side in the second direction, and a fourth inner surface portion located on the other side in the first direction as it goes from an end portion of the second inner surface on the other side in the second direction to one side in the second direction, and
an end portion of the fourth inner surface portion on one side in the second direction is connected to an end portion of the third inner surface portion on the other side in the second direction.
